(19) United States
(12) Patent Application Publication
(10) Pub. No.: US 2016/0322514 A1
(43) Pub. Date: Nov. 3, 2016

(54) Solar Cells and Methods of Manufacturing Solar Cells Incorporating Effectively Transparent 3D Contacts

(71) Applicant: California Institute of Technology, Pasadena, CA (US)

(72) Inventors: Harry A. Atwater, South Pasadena, CA (US); Rebecca Saive, Pasadana, CA (US); Aleca M. Borsuk, Pasadena, CA (US); Hal Emmer, Pasadena, CA (US); Colton Bukowsky, Pasadena, CA (US); Sisir Yalamanchili, Pasadena, CA (US)

(73) Assignee: California Institute of Technology, Pasadena, CA (US)

(21) Appl. No.: 15/144,807

(22) Filed: May 2, 2016

Related U.S. Application Data
(60) Provisional application No. 62/156,034, filed on May 1, 2015.
(60) Provisional application No. 62/233,014, filed on Sep. 25, 2015.

(51) Int. Cl. H01L 31/02; H01L 31/18; H01L 31/0232

(52) U.S. Cl. CPC H01L 31/02008; H01L 31/02327; H01L 31/18

(57) ABSTRACT

Solar cells in accordance with a number of embodiments of the invention incorporate effectively transparent 3D contacts that redirect light incident on the contacts onto the photoabsorbing surfaces of the solar cells. One embodiment includes a photoabsorbing surface and a plurality of three-dimensional contacts formed on the photoabsorbing surface. The plurality of three-dimensional contacts are spaced apart so that radiation is incident on a portion of the photoabsorbing surface. In addition, the three-dimensional contacts include at least one surface that redirects radiation incident on the three-dimensional contacts onto the photoabsorbing surface. Processes for manufacturing solar cells in accordance with many embodiments of the invention include: fabricating prototype three-dimensional contacts; forming a master structure for use in a gravure printing process using the prototype three-dimensional contacts; and forming three-dimensional contacts using a printing material formed on a substrate material using the master structure in a gravure printing process.

### CROSS-REFERENCE TO RELATED APPLICATIONS

The current application claims priority to U.S. Provisional Patent Application No. 62/156,034, entitled “3D Transparent Contacts for Solar Cells” filed May 1, 2015, and U.S. Provisional Patent Application No. 62/233,014, entitled “Effectively Transparent Solar Cell Front Contacts” filed Sep. 25, 2015. The disclosures of U.S. Provisional Patent Application Nos. 62/156,034 and 62/233,014 are hereby incorporated by reference herein in their entirety.

### FIELD OF THE INVENTION

The present invention relates generally to photovoltaics and more specifically to incorporation of three-dimensional front contacts in photovoltaics.

### BACKGROUND OF THE INVENTION

Photovoltaics are an ever-increasing component of the world's rapidly growing renewable carbon-free electricity generation infrastructure. In recent years, the photovoltaics field has dramatically expanded owing to the large-scale manufacture of inexpensive crystalline Silicon and thin film cells and modules. Silicon solar cells typically utilize a heterostructure intrinsic thin layer (HIT) design to enable increased open circuit voltage. Many mass-manufacturable HIT cell architectures feature front contacts.

### SUMMARY OF THE INVENTION

Solar cells in accordance with a number of embodiments of the invention incorporate effectively transparent 3D contacts that redirect light incident on the contacts onto the photoabsorbing surfaces of the solar cells. Many photons incident on conventional solar cells do not generate current due to reflection of the photons by metallic contacts formed on the surface of the solar cells. By replacing conventional strip contacts with contacts shaped to reflect incident light onto photoabsorbing surfaces of the solar cells, the overall efficiency with which the solar cell converts incident solar energy into electricity can be increased. In many embodiments, the 3D contacts are designed to reflect a majority of radiation directly incident on the contacts onto the photoabsorbing surfaces of the solar cells. In several embodiments, the shape of the 3D contacts is such that a majority of radiation incident on the contacts is redirected onto the photoabsorbing surfaces of the solar cells at angles of incidence as great as thirty degrees.

One embodiment of the invention is a solar cell that includes: a photoabsorbing surface; and a plurality of three-dimensional contacts formed on the photoabsorbing surface and spaced so that radiation is incident on the photoabsorbing surface, where at least one three-dimensional contact includes at least one surface that redirects radiation incident on the surface of the three-dimensional contact onto the photoabsorbing surface.

In a further embodiment, the at least one three-dimensional contact has a triangular cross-section.

In another embodiment, at least one three-dimensional contact has a triangular cross-section with a base adjacent the photoabsorbing surface having a width that is smaller than the height of the triangular cross-section extending away from the photoabsorbing surface.

In a still further embodiment, the at least one three-dimensional contact is formed from a non-conductive gel coated in a reflective material.

In still another embodiment, the non-conductive gel is a silica sol gel and the reflective material is silver.

In a yet further embodiment, the at least one three-dimensional contact is formed from a conductive ink.

In yet another embodiment, the height of the triangular cross-section is at least 7 μm.

In a further embodiment again, the base width of the triangular cross-section is 2.5 μm and the height of the triangular cross-section is 7 μm.

In another embodiment again, the at least one three-dimensional contact has a at least one surface with a parabolic shape.

In a further additional embodiment, the transparency of the plurality of three-dimensional contacts is at least 99.96%.

In another additional embodiment, the sheet resistance of the solar cell is no more than 4.8 Ω/sq.

An embodiment of the method of the invention includes: fabricating prototype three-dimensional contacts; forming a master structure for use in a gravure printing process using the prototype three-dimensional contacts; and forming three-dimensional contacts using a printing material formed on a substrate material using the master structure in a gravure printing process, where the three-dimensional contacts include at least one surface configured to redirect radiation incident on the surface of the three-dimensional contact onto the substrate material on which the three-dimensional contact is formed.

In a further embodiment, fabricating prototype three-dimensional contacts comprises fabricating prototype three-dimensional contacts using a lithography process.

In another embodiment, the lithography process includes a three-dimensional writing by two-photon lithography.

In a still further embodiment, fabricating prototype three-dimensional contacts comprises directional etching of a substrate to form the prototype three-dimensional contacts.

In still another embodiment, the three-dimensional contacts have a triangular cross section.

In a yet further embodiment, the printing material is a non-conductive silica sol gel.

Yet another embodiment also includes coating the printing material formed on the substrate material with a reflective coating material.

In a further embodiment again, the reflective coating material is silver.

Another further embodiment includes: a photoabsorbing surface; and a plurality of three-dimensional contacts formed on the photoabsorbing surface and spaced so that radiation is incident on the photoabsorbing surface, where at least one three-dimensional contact includes at least one surface that redirects radiation incident on the surface of the three-dimensional contact onto the photoabsorbing surface. In addition, the at least one three-dimensional contact has a triangular cross-section with a base adjacent the photoabsorbing surface having a width that is smaller than the height of the triangular cross-section extending away from the photoabsorbing surface; the transparency of the plurality of three-dimensional contacts is at least 99.96%; and the sheet resistance of the solar cell is no more than 4.8 Ω/sq.

### BRIEF DESCRIPTION OF THE DRAWINGS

FIG. 1A conceptually illustrates absorption by a conventional solar cell.

FIG. 1B conceptually illustrates reflection by the front contacts of a solar cell

FIG. 1C conceptually illustrates a solar cell incorporating a transparent 3D contact in accordance with an embodiment of the invention.

FIG. 2A shows optical simulations of the transmitted power through triangular cross-section and flat front contacts with 40 μm periodicity and 2.5 μm width as a function of wavelength for the AM 1.5G spectrum.

FIG. 2B shows the dependence of the transmittance on the angle of incident light at 550 nm.

FIG. 2C shows wavelength dependent reflection measurements of different areas on a HIT solar cell.

FIG. 2D illustrates the angle dependence of the reflection measured at 550 nm.

FIGS. 3A and 3B show the steady-state electric field magnitude distribution of a free-standing triangular contact and a flat contact respectively with 550 nm plane wave light incident at the top of the simulation cell.

FIGS. 3C and 3D show three-dimensional confocal scanning microscope measurements of a flat grid line contact and triangular cross-section contact on a HIT solar cell respectively.

FIGS. 4A-4D show spatially resolved reflection of line contacts (FIG. 4A) and triangle contacts (FIG. 4C) and the corresponding spatially resolved photocurrent for the line contacts (FIG. 4B) and the triangle contacts (FIG. 4D) determined by laser beam induced photocurrent measurements at a wavelength of 543 nm.

FIG. 4E shows line-scan profiles of the photocurrent taken across flat contact lines and across lines of contacts with triangular cross-sections.

FIGS. 5A-5C show spatially resolved photocurrent for (FIG. 5A) contact lines and (FIG. 5B) triangle contacts determined by laser beam induced photocurrent measurements at a wavelength of 543 nm, and (FIG. 5C) line scan profiles of the photocurrent taken across flat contact lines and across lines with triangular cross-sections.

FIGS. 6A-6E show scanning electron microscope images of (FIG. 6A) a two-photon lithography prepared triangle, (FIG. 6B) the master structure for the gravure-printed triangular cross-section structure shown in (FIG. 6C), (FIG. 6D) a printed device with triangles aligned on a finger grid, (FIG. 6E) a triangular cross-section structure directly etched onto silicon.

FIG. 7 shows a tandem solar cell device in accordance with an embodiment of the invention.

### DETAILED DISCLOSURE OF THE INVENTION

Turning now to the drawings, solar cells and processes for manufacturing solar cells incorporating effectively transparent 3D contacts (transparent 3D contacts) that redirect light onto the active photoabsorbing surface of the solar cell in accordance with various embodiments of the invention are illustrated. Transparent 3D contacts in accordance with many embodiments of the invention include at least one surface that is configured to redirect light incident on the surface onto the photoabsorbing surfaces of the solar cells. In several embodiments, the transparent 3D contacts have triangular cross-sections. In certain embodiments, the triangular cross-sections can be equilateral triangles (having a base that is wider than the height of the triangle), isosceles triangles, right angle triangles, scalene triangles, or obtuse triangles. In various embodiments, the triangles are constructed to have heights that are greater than the base width of the triangles (i.e. the surface closest to the photoabsorbing surface has a width that is less than the height to which the triangle extends above the photoabsorbing surface). In many embodiments, a surface of the transparent 3D contact has a parabolic shape. In other embodiments, any of a variety of surface shapes can be utilized that redirect light incident on the contacts onto the photoabsorbing surfaces of the solar cells.

When constructed in accordance with a number of embodiments of the invention, the 3D contacts can be effectively transparent, and highly conductive. The contacts can be incorporated within most types of flat plate solar cells. Spatially resolved photocurrent measurements show that transparency of up to 99.96% can be achieved while obtaining a low sheet resistance of 4.8 Ω/sq. In many embodiments, large-scale fabrication of solar cells incorporating transparent 3D contacts can be achieved by gravure printing of contacts. Solar cells and methods of constructing solar cells incorporating transparent 3D contacts in accordance with various embodiments of the invention are discussed further below.

### Effective Transparency

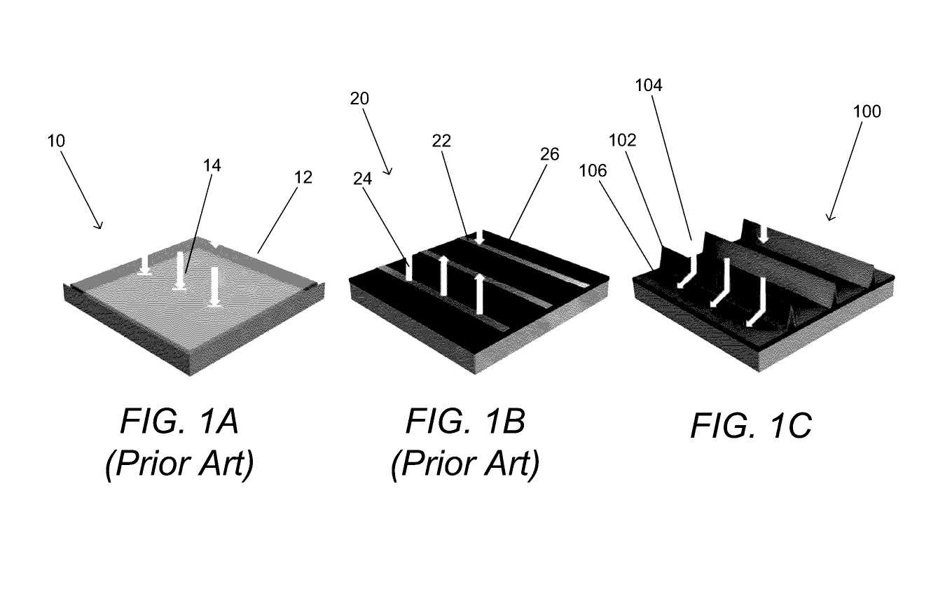

In conventional solar cells with front and rear contacts, a non-negligible fraction of the incoming solar power is immediately lost at the front contact either through absorption, as in the case of transparent conductive oxides or though reflection by the front contacts. Absorption by a conventional solar cell is conceptually illustrated in FIG. 1A. The illustrated solar cell 10 includes a transparent conductive oxide 12 layer that absorbs incident radiation 14. Reflection by the front contacts of a solar cell is conceptually illustrated in FIG. 1B. The illustrated solar cell 20 includes a number of front electrodes in the form of linear traces 22 that reflect incident radiation 24 that is incident on the front electrodes. In such a configuration, only photons incident on an active photoabsorbing surface 26 are capable of conversion to electric current. Approaches for mitigating solar cell front contact losses can include using less absorbing transparent conductive oxides, or less reflective metal contacts. Achieving improved transparency using these approaches typically results in reduced conductivity, which in turn leads to series resistance electrical losses in the solar cell.

Solar cells in accordance with many embodiments of the invention incorporate effectively transparent front contacts. The front contacts are effectively transparent in the sense that they are formed with three dimensional (3D) shapes that reflect or redirect incident photons onto the active photoabsorbing surface of the solar cell. Solar cells in accordance with several embodiments of the invention overcome shadowing losses and parasitic absorption without reducing the conductivity of the contacts relative to conventional strip contacts. A solar cell incorporating a transparent 3D contact in accordance with an embodiment of the invention is conceptually illustrated in FIG. 1C. The solar cell 100 includes triangular cross-section contact lines 102 that are configured to redirect scattered light 104 incident on the front contact to an active photoabsorbing surface 106 of the solar cell. In this way, the triangular cross-section contact lines can perform as effectively transparent and highly conductive front contacts.

Although triangular cross-section contacts are described above with reference to the solar cell illustrated in FIG. 1C, any of a variety of transparent 3D contacts having profiles that redirect incident radiation in a manner appropriate to the requirements of specific solar cell applications can be utilized in accordance with various embodiments of the invention. Heterojunction solar cells incorporating a variety of different transparent 3D contact structures and methods of manufacturing heterojunction solar cells incorporating transparent 3D contacts in accordance with a number of embodiments of the invention are discussed further below.

### Heterojunction Solar Cells Incorporating Transparent 3D Contacts

For flat plate solar cells, the front contact design process typically involves a balance of the grid finger resistance, grid finger shadow loss, and the sheet resistance and absorption losses associated with planar layers that facilitate lateral majority carrier transport to the grid fingers. In silicon heterojunction solar cells, this process typically involves a trade-off between grid finger resistance and the sheet resistance and transmission losses of the transparent conducting oxide/amorphous silicon structures coating the cell front surface. Use of effectively transparent 3D contacts in accordance with various embodiments of the invention is conceptually quite general and applicable to almost any front-contacted solar cell. Simulations and experimental results suggest that use of effectively transparent 3D contacts having a triangular cross-section rather than conventional front contacts has the potential to provide 99.96% optical transparency with a sheet resistivity of 4.8 Ω/sq. Similar results can be obtained when utilizing transparent 3D contacts in InGaP based solar cells. Various simulations and experimental results are discussed below.

### Optical Simulations and Measurements

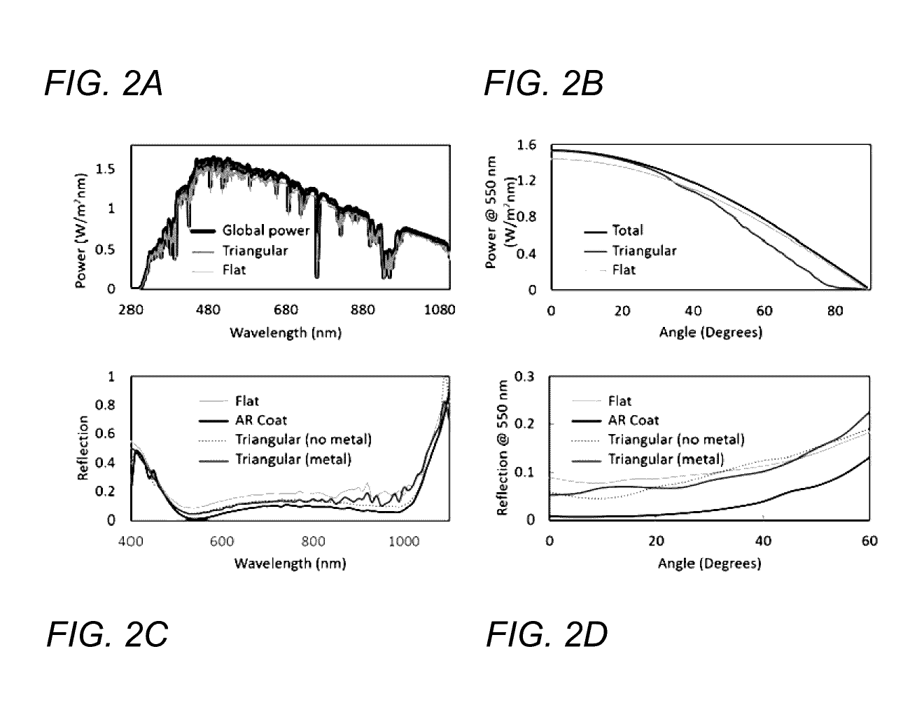

FIG. 2A shows optical simulations of the transmitted power through triangular cross-section and flat front contacts with 40 μm periodicity and 2.5 μm width as a function of wavelength for the AM 1.5G spectrum. It can be seen that flat contacts decrease the transmitted power while triangular contacts transmit almost all of the incident light. For silicon solar cells, full transmission of normally incident light yields up to a 44.05 mA/cm2 short circuit current density. Adding flat contact fingers causes this value to decreases to 41.25 mA/cm2 in simulation, but 43.83 mA/cm2 can be achieved using triangular cross-section contacts. FIG. 2B shows the dependence of the transmittance on the angle of incident light at 550 nm. It can be seen that triangular contacts outperform flat contacts between 0 and 35 degrees incident angle.

FIG. 2C shows wavelength dependent reflection measurements of different areas on a HIT solar cell. The reflection increases in the shorter wavelength regime due to the higher refractive index of the amorphous silicon, whereas reflection increases for wavelengths beyond 1000 nm due to incomplete light absorption and reflection of light at the cell back surface (wafer thickness 280 μm). An area with only the antireflection (AR) coating and no front contact lines shows the lowest reflection over a broad wavelength range, while an area with flat front contact lines shows the highest reflection. Triangular cross-section lines with and without metal exhibit reduced reflection compared to flat lines but more reflection than the regions with bare coating. The illumination spot size used in these measurements is large (˜200 μm), and averages over many front contact lines. FIG. 2D illustrates the angle dependence of the reflection measured at 550 nm. As predicted from simulations, the triangular cross-section contacts perform better than flat contact lines for incident angles smaller than 40 degrees from the surface normal.

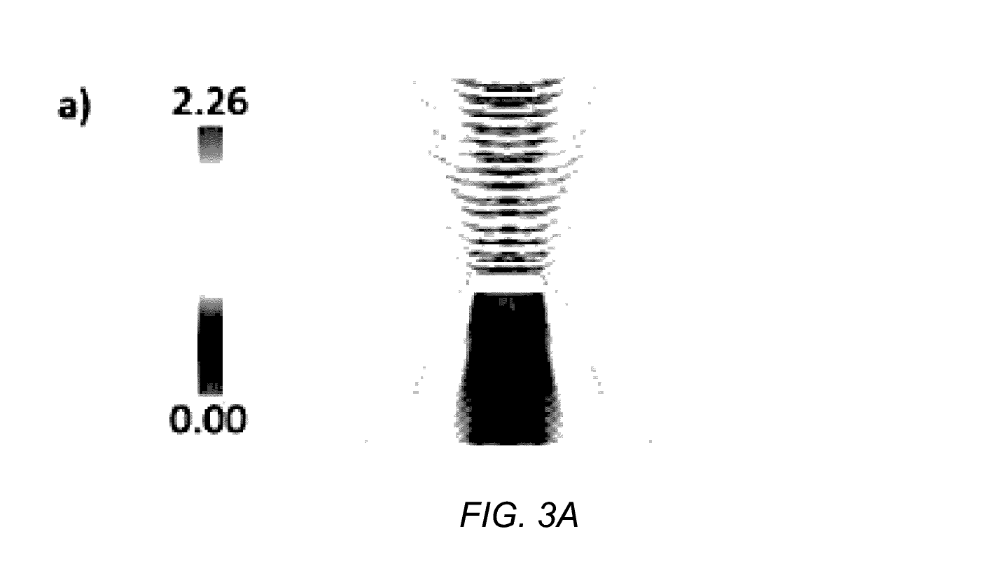

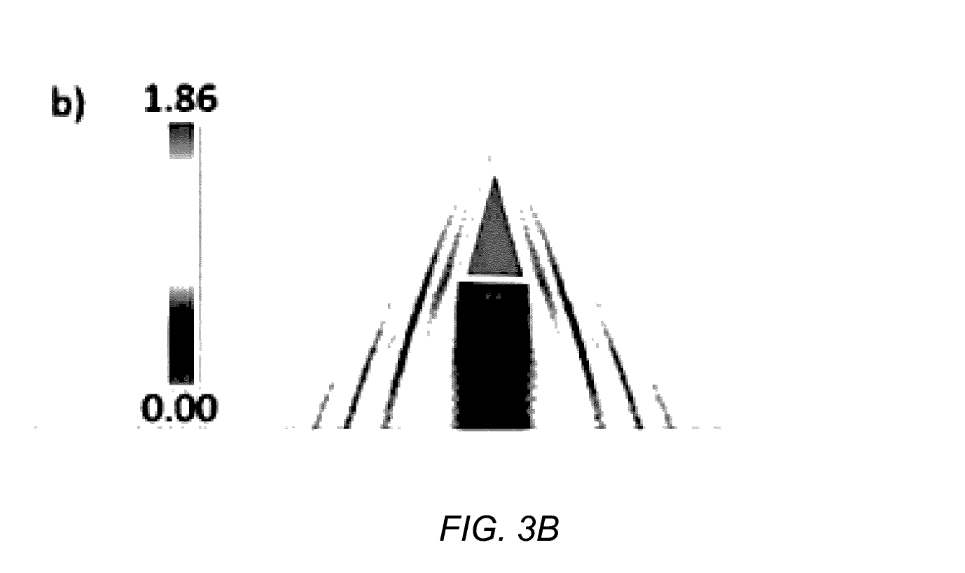

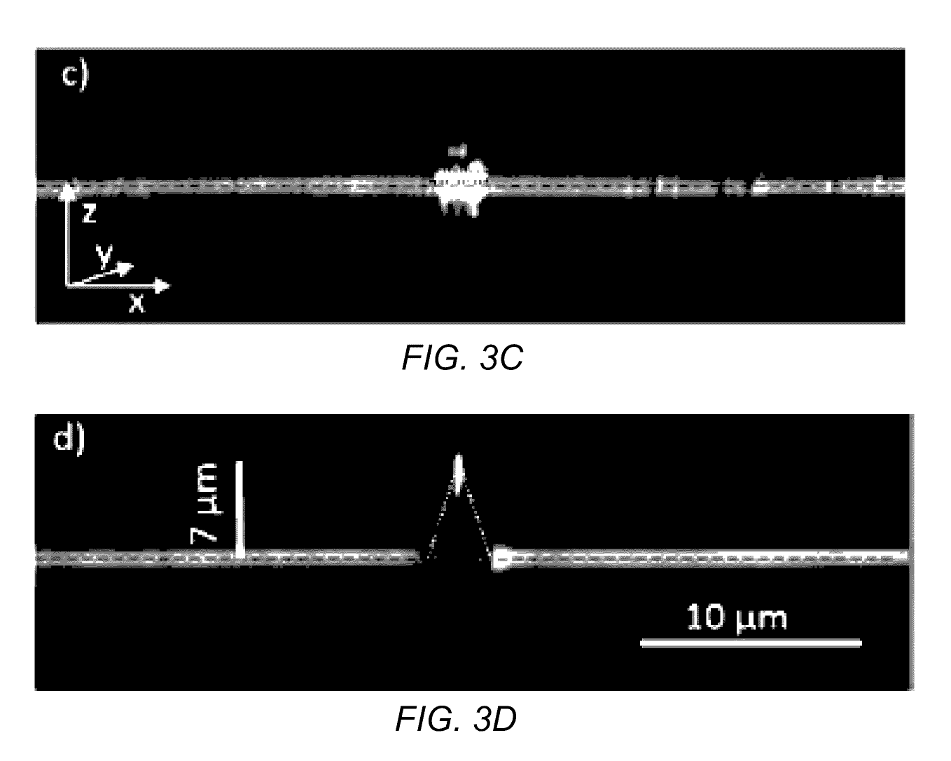

FIGS. 3A and 3B show the steady-state electric field magnitude distribution of a free-standing triangular contact and a flat contact respectively with 550 nm plane wave light incident at the top of the simulation cell. For planar contacts, part of the incident light is reflected back toward the incidence direction, as is apparent from the high electric field density above the contact plane. By contrast, the triangular cross-section contact does not exhibit a similar back-reflection, as indicated by the lack of an increased electric field density in the incidence direction. However electric field enhancement is seen in the forward scattering direction, behind the contact, explaining its effective transparency.

FIGS. 3C and 3D show three-dimensional confocal scanning microscope measurements of a flat grid line contact and triangular cross-section contact on a HIT solar cell respectively. The laser focus was scanned in x-, y- and z-direction and the presented images show a cross-section of the signal at constant y-value. A dashed black line in each image marks the solar cell surface. In FIG. 3C it can be seen that in the vicinity of the flat contact (dashed black rectangle) the reflection signal is much stronger than at the AR coated solar cell substrate. In FIG. 3D the position of the triangle is marked by a dashed white triangle. Along the sidewalls it appears black proving that there is no reflection back to the incident light source from the sidewalls. Only the tip shows some reflection which can be attributed to finite tip curvature as confirmed by optical simulations.

### Spatially Resolved Reflection and Photocurrent

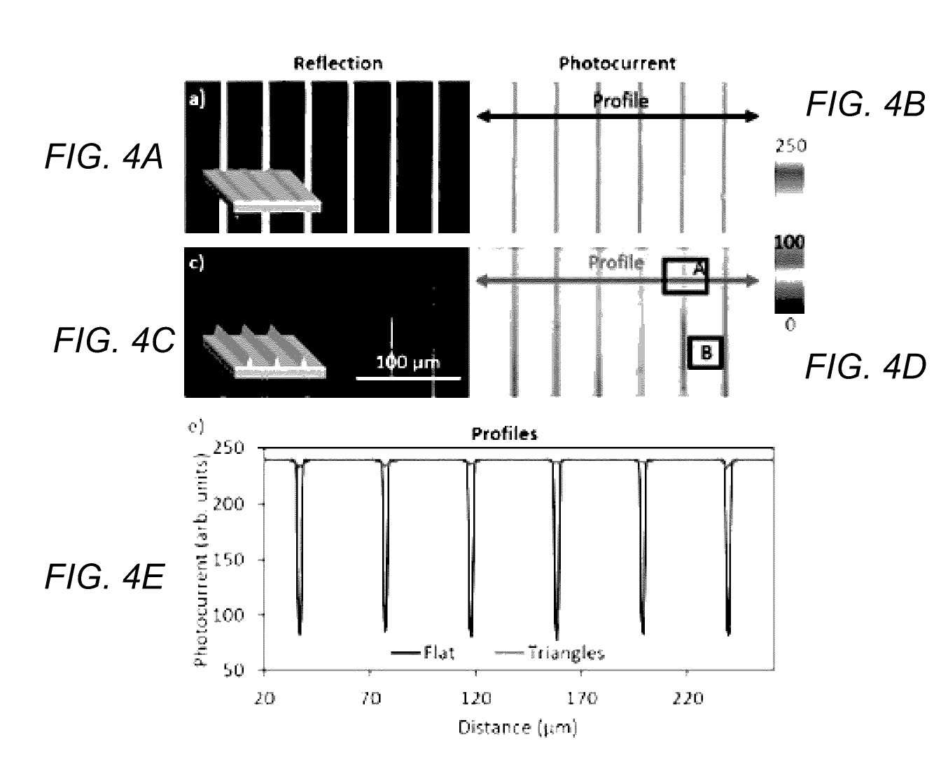

FIGS. 4A-4D show spatially resolved measurements of the reflection (FIGS. 4A and 4C) and the photocurrent (FIGS. 4B and 4D) of an area with flat contacts (FIGS. 4A and 4B) and with triangular cross-section contacts (FIGS. 4C and 4D) on the same cell. In FIG. 4A the dark regions correspond to the substrate with AR coating while the bright regions correspond to the flat silver grid fingers. In FIG. 4C triangular cross-section lines cover the contacts in a different area on the same cell. It can be seen that the triangular cross-section contacts appear much darker than the flat line contacts, in some regions showing almost no reflection. This has direct influence on the measured photocurrent. As can be seen in FIG. 4B, the bright red color represents the photocurrent measured in the areas between contact lines, while the dark green color corresponds to the contact lines, illustrating that there is very little photocurrent generated at the position of the flat contact lines. FIG. 4D however shows the photocurrent in the vicinity of the triangular cross-section contacts and the photocurrent at the position of the triangular lines is relatively higher as seen by the red color, while the photocurrent between contact lines is the same as in FIG. 4B. The difference in photocurrent collection near the contacts becomes very apparent when comparing line-scan profiles of the photocurrent taken across flat contact lines and across lines with triangular cross-section, as shown in FIG. 4E. Integrating over the whole measured area in FIG. 4B leads to a generation photocurrent density of 96.99% compared to the contact-free regions in between the lines (e.g. box labeled as ‘B’ in FIG. 4D). The whole area shown in FIG. 4D leads to a generation current density of 99.78% while one particularly good area marked by a box with the label ‘A’ even reaches 99.96%. We note that the spatially-resolved photocurrent maps in FIGS. 4A-4E indicate the potential for effectively transparent contacts. The measurements of FIG. 2, which show a larger reflectance for triangle cross-section contacts than those indicated in FIGS. 4A-4E, are an average over a larger area, and thus represent an average over regions with good fidelity in the fabricated triangular cross-section contact structure, along with regions containing imperfections. Thus the bigger (˜200 μm) laser spot size used for the wavelength- and angle-dependent reflectance measurements, which includes areas with imperfect triangular contacts, measures a higher overall reflectivity, while the selected-area results of FIGS. 4A-4E illustrate the intrinsic potential of transparent 3D contacts.

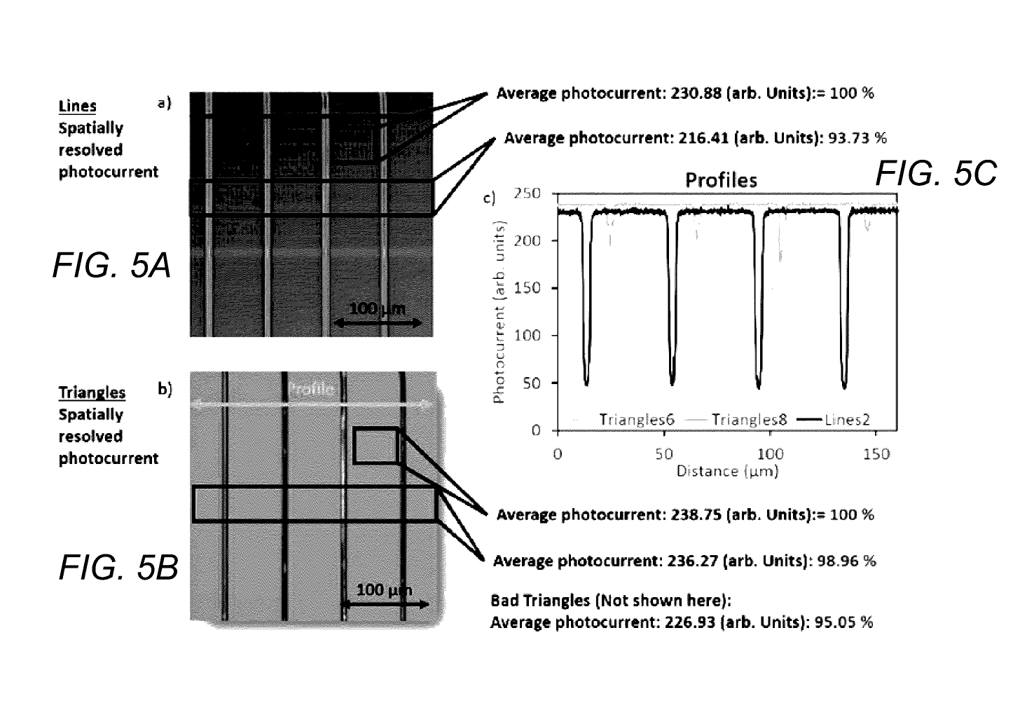

Even triangular cross-section structures which only include the two-photon lithography resist and are not metal coated improve the photocurrent as shown in FIGS. 5A-5C. While lines decreased the photocurrent to 93.73% on this solar cell compared to an area with only the AR coating, triangular cross-section lines without metal coating achieve a photocurrent of 98.96%.

### Methods of Manufacturing HIT Solar Cells Incorporating Transparent 3D Contacts

A number of processes are known in the art for preparation of heterojunction with intrinsic thin layer (HIT) cells. In a number of embodiments, HIT cells can be constructed using a thin indium tin oxide (ITO) layer (e.g. 18 nm) to provide high optical transmission while providing good electrical contact to the amorphous silicon. In other embodiments, any of a variety of thicknesses and materials can be utilized in the construction of the solar cells on which the transparent 3D contacts are formed. The formation of the transparent 3D contacts is discussed further below.

HIT solar cells can be manufactured by fabricating prototype 3D contacts using three-dimensional writing by two-photon lithography, and these prototypes can then be used as master molds for a gravure printing process.

Two-photon lithography refers to a “direct laser writing” approach that can be used to form three-dimensional micro- and nanostructures in photo-sensitive materials. Two-photon lithography utilizes a non-linear two-photon absorption process. Many resins that polymerize when exposed to UV-light can undergo similar chemical reactions when two photons of near-infrared light are absorbed simultaneously. For this effect to occur, a sufficiently high light intensity can be provided by an ultrashort pulse laser. Typically, the laser is focused into a resin and the two-photon polymerization (TPP) is triggered only in the focal spot volume.

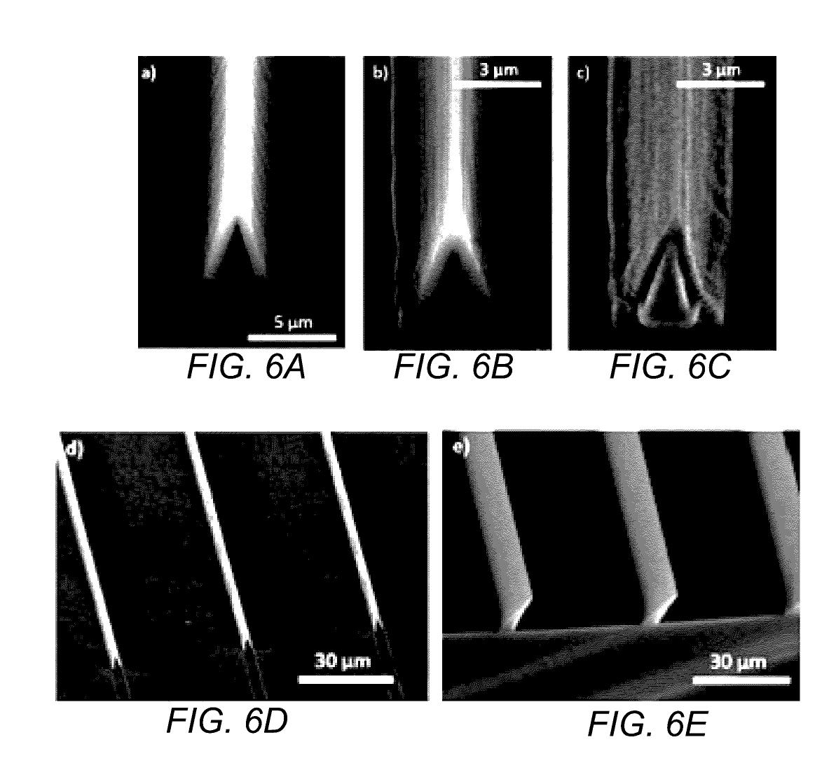

HIT solar cells similar to the HIT solar cells utilized to conduct the measurement discussed above can be formed by first lithographically defining a flat aluminum finger grid with 2.5 μm width and 40 μm period on planar HIT solar cells. As discussed above, three-dimensional two photon lithography can be used to prepare triangular shaped lines. In a number of embodiments, the triangular shaped lines can have 2.5 μm width and 7 μm height. A scanning electron microscope image of such a structure is shown in FIG. 6A. In a number of embodiments, the two-photon lithography can be performed using a two-photon lithography machine such as (but not limited to) the Photonotic Professional GT distributed by Nanoscribe GmbH located in Eggenstein-Leopoldshafen, Germany.

Gravure printing can provide high resolution prints and typically involves a gravure cylinder that holds the master and transfers a printed material to a substrate through surface interactions in a zone between an impression roller and the gravure cylinder. In the illustrated embodiment, the material that is printed is a non-conductive silica sol gel. If instead of the process described above a conductive ink were to be used, the printed structures could be used for current transport throughout the whole triangular cross sectional conductor, leading to very low sheet resistance. In other embodiments, any material can be used in a gravure printing process to create transparent 3D contacts in accordance with an embodiment of the invention.

Referring again to the process for manufacturing HIT solar cells similar to the HIT solar cells utilized to conduct the measurement discussed above, triangular cross-section contacts prepared by two photon lithography can be used as master samples to prepare stamps for a gravure printing process. A master structure formed from the prototype described above in accordance with an embodiment of the invention is shown in FIG. 6B. The stamps can be filled with a silica sol gel and triangles stamped onto a substrate. A SEM image of a gravure printed structure in accordance with an embodiment of the invention is shown in FIG. 6C and it can be seen that even the sidewall texture was reproduced. The printed 3D contact structures can be coated with silver by evaporation under an angle such that only triangle walls became metalized while the active surface remains free of metal. FIG. 6D shows an SEM image of a triangular cross-section contacts aligned to flat finger contacts.

In the configuration described above the sheet resistance is determined by the flat finger grid. Calculating the sheet resistance for the presented geometry (silver lines with 2.5 μm width, 100 nm thickness and 40 μm distance) leads to 2.6 Ω/sq. Actual measurements were a higher value (4.8 Ω/sq) as the lines are not perfectly homogeneous and discontinuous in some areas. Note, that this value can be adapted by altering thickness, width and distance of the contact lines.

Although specific materials and dimensions are described above for manufacturing solar cells incorporating transparent 3D contacts, any of a variety of processes and materials appropriate to the requirements of specific applications can be utilized in accordance with various embodiments of the invention. For example, the width, height, shape, and/or material composition of the transparent 3D contacts can be modified as appropriate to the requirements of a specific solar cell application. In addition, any of a variety of fabrication processes can be utilized in the construction of transparent 3D contacts as appropriate to the requirements of a specific manufacturing process. Alternative processes involving the use of directional etching to form masters for gravure printing in accordance with certain embodiments of the invention are discussed further below.

### Forming Masters Using Directional Etching

Another approach to cross-section contact master fabrication is via directional dry etching. Formation of high aspect ratio lines with triangular cross-sections by directional dry-etching into silicon in accordance with an embodiment of the invention is illustrated in FIG. 6E. In a number of embodiments, these structures are used as master molds for a large-scale gravure printing process for fabricating effectively transparent 3D contacts on substrates utilized in the construction of solar cells.

In several embodiments, triangular lines can be defined using an etch mask of Al₂O₃ defined lithographically and then, a cryogenic inductively coupled plasma reactive ion etching can be performed with SF₆ as etching gas and O₂ as passivation gas. The tapering of the triangles can be adjusted by varying the SF₆/O₂ ratio in the plasma. In a number of embodiments, an initial line pattern with approximately 2.5 μm width can be used and the etching can be performed using a 900 W inductively coupled plasma, a 5 W capacitive coupled plasma, 70 sccm SF₆ and 9 sccm O₂ for 10 minutes at −120° C. in an inductively couple plasma etching system such as, but not limited to, the PlasmaPro 100 distributed by Oxford Instruments plc of Abingdon, United Kingdom.

While specific processes are described above for the formation of transparent 3D contacts on substrates utilized in solar cells, any of a variety of processes appropriate to the requirements of specific solar cell fabrication processes can be utilized in accordance with embodiments of the invention.

### Using 3D Contacts for Tandem Solar Cells

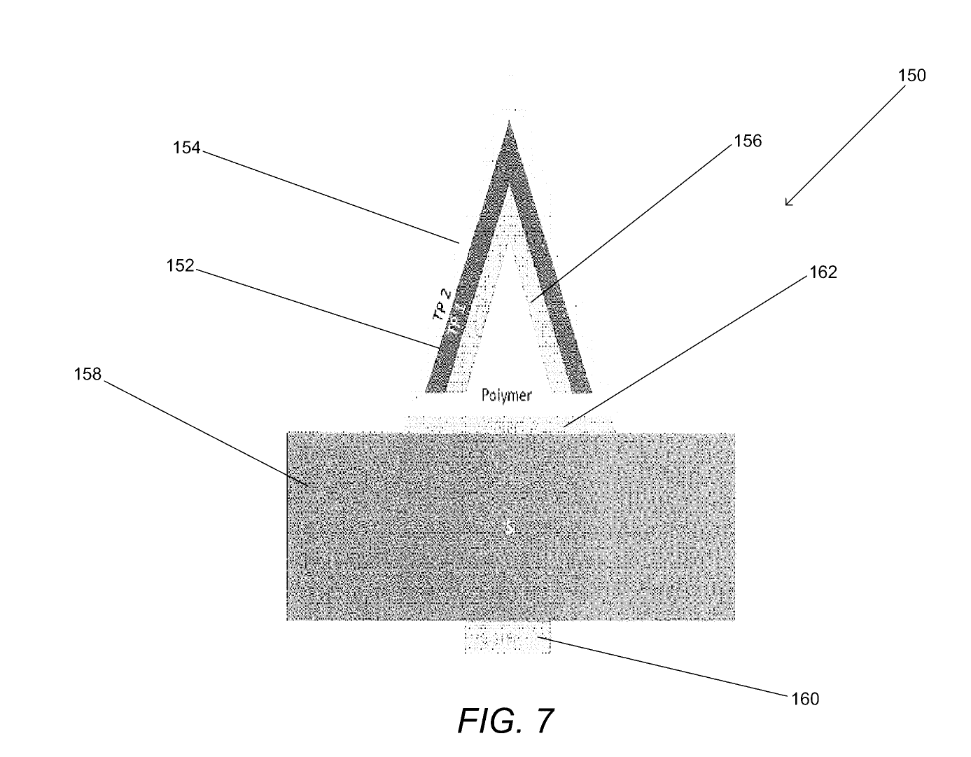

Transparent 3D contact structures in accordance with several embodiments of the invention can be used to implement a tandem solar cell device. A tandem solar cell device in accordance with an embodiment of the invention is illustrated in FIG. 7. The tandem solar cell 150 is made by forming materials (152, 154) with a higher band gap than Silicon on top of a 3D metal contact 156. Therefore, photons with energy higher than the band gap of tandem partner 1 and 2 (152, 154) will be absorbed in the tandem partner cell while photons with lower energy will be redirected to the Silicon (158). In FIG. 7, the tandem solar cell is shown as a three terminal device (156, 160, 162), which means there is on contact on the backside of the Silicon (160), one contact (162) on the front side of the Silicon, which acts as the contact for tandem partner 2, and there is one contact (164) for tandem partner 1, which t the same time provides the redirection of light.

Although specific tandem solar cell devices are described above with respect to FIG. 7, any of a variety of materials can be utilized to construct tandem solar cells incorporating materials, having higher band gaps than the band gap of the bulk photoabsorbing material of the solar cell, formed on top of one or more 3D contacts as appropriate to the requirements of specific applications in accordance with various embodiments of the invention.

Although the present invention has been described in certain specific aspects, many additional modifications and variations would be apparent to those skilled in the art. It is therefore to be understood that the present invention may be practiced otherwise than specifically described, including various changes in the implementation such as utilizing transparent 3D contacts that have different cross-sections than those described herein, without departing from the scope and spirit of the present invention. Thus, embodiments of the present invention should be considered in all respects as illustrative and not restrictive.

What is claimed is:

1. A solar cell, comprising:
a photoabsorbing surface; and
a plurality of three-dimensional contacts formed on the photoabsorbing surface and spaced so that radiation is incident on a portion of the photoabsorbing surface, where at least one three-dimensional contact includes at least one surface that redirects radiation incident on the surface of the three-dimensional contact onto the photoabsorbing surface.

2. The solar cell of claim 1, wherein the at least one three-dimensional contact has a triangular cross-section.

3. The solar cell of claim 2, wherein at least one three-dimensional contact has a triangular cross-section with a base adjacent the photoabsorbing surface having a width that is smaller than the height of the triangular cross-section extending away from the photoabsorbing surface.

4. The solar cell of claim 3, wherein the at least one three-dimensional contact is formed from a non-conductive gel coated in a reflective material.

5. The solar cell of claim 4, wherein the non-conductive gel is a silica sol gel and the reflective material is silver.

6. The solar cell of claim 3, wherein the at least one three-dimensional contact is formed from a conductive ink.

7. The solar cell of claim 3, wherein the height of the triangular cross-section is at least 7 μm.

8. The solar cell of claim 3, wherein the base width of the triangular cross-section is 2.5 μm and the height of the triangular cross-section is 7 μm.

9. The solar cell of claim 1, wherein the at least one three-dimensional contact has a at least one surface with a parabolic shape.

10. The solar cell of claim 1, wherein the transparency of the plurality of three-dimensional contacts is at least 99.96%.

11. The solar cell of claim 10, wherein the sheet resistance of the solar cell is no more than 4.8 Ω/sq.

12. A method of manufacturing a solar cell using three dimensional gravure printing, comprising:
fabricating prototype three-dimensional contacts;
forming a master structure for use in a gravure printing process using the prototype three-dimensional contacts; and
forming three-dimensional contacts using a printing material formed on a substrate material using the master structure in a gravure printing process, where the three-dimensional contacts include at least one surface configured to redirect radiation incident on the surface of the three-dimensional contact onto the substrate material on which the three-dimensional contact is formed.

13. The method of claim 12, wherein fabricating prototype three-dimensional contacts comprises fabricating prototype three-dimensional contacts using a lithography process.

14. The method of claim 13, wherein the lithography process includes a three-dimensional writing by two-photon lithography.

15. The method of claim 12, wherein fabricating prototype three-dimensional contacts comprises directional etching of a substrate to form the prototype three-dimensional contacts.

16. The method of claim 12, wherein the three-dimensional contacts have a triangular cross section.

17. The method of claim 12, wherein the printing material is a non-conductive silica sol gel.

18. The method of claim 17, further comprising coating the printing material formed on the substrate material with a reflective coating material.

19. The method of claim 18, wherein the reflective coating material is silver.

20. A solar cell, comprising:
a photoabsorbing surface; and
a plurality of three-dimensional contacts formed on the photoabsorbing surface and spaced so that radiation is incident on a portion of the photoabsorbing surface, where at least one three-dimensional contact includes at least one surface that redirects radiation incident on the surface of the three-dimensional contact onto the photoabsorbing surface;
wherein the at least one three-dimensional contact has a triangular cross-section with a base adjacent the photoabsorbing surface having a width that is smaller than the height of the triangular cross-section extending away from the photoabsorbing surface;
wherein the transparency of the plurality of three-dimensional contacts is at least 99.96%; and
wherein the sheet resistance of the solar cell is no more than 4.8 Ω/sq.
